(19) United States
(12) Patent Application Publication
(10) Pub. No.: US 2011/0240986 A1
(43) Pub. Date: Oct. 6, 2011

(54) PIXEL STRUCTURE OF ELECTROLUMINESCENT DISPLAY PANEL AND METHOD OF MAKING THE SAME

(76) Inventors: Tsung-Ting Tsai, Hsin-Chu (TW); Hsing-Hung Hsieh, Hsin-Chu (TW)

(21) Appl. No.: 12/875,144

(22) Filed: Sep. 3, 2010

(30) Foreign Application Priority Data
Apr. 6, 2010 (TW) 099110542

(51) Int. Cl. H01L 33/08; H01L 33/28

(52) U.S. Cl. 257/43; 438/34; 257/E33.019; 257/E33.053

(57) ABSTRACT

A pixel structure of an electroluminescent display panel includes a substrate, a first patterned conductive layer, an insulating layer, a second patterned conductive layer, an active layer, a first passivation layer and an electroluminescent device. The first patterned conductive layer includes a gate. The insulating layer, disposed on the substrate and the first patterned conductive layer, has at least a first contact hole partially exposing the gate. The second patterned conductive layer, disposed on the insulating layer, includes a first source, a first drain, and a second drain, where the second drain is electrically connected to the gate through the first contact hole of the insulating layer.

### BACKGROUND OF THE INVENTION

1. Field of the Invention

The present invention relates to a pixel structure of an electroluminescent display panel and method of making the same, and more particularly, to a pixel structure of an electroluminescent display panel in which a second drain of a second switch element is electrically connected to a gate of a first switch element without requiring a third conductive layer as a connection line, and a method of making the same.

2. Description of the Prior Art

Active matrix organic light emitting diode (AMOLED) display panel possesses many advantages such as compatibility to low temperature process, feasibility to large size display, fast response, low voltage, high efficiency, self illumination and wild viewing angle, and therefore has been expected to be the mainstream product of display panel in the future.

Please refer to FIG. 1. FIG. 1 is a cross-sectional view illustrating a pixel structure of a conventional organic light emitting diode (OLED) display panel. As shown in FIG. 1, the pixel structure 1 of the conventional OLED display panel includes a thin film transistor (TFT) 2, and an organic light emitting diode OLED. The TFT 2 is a bottom-gate type TFT including a gate 3, a source 4 and a drain 5. The source 4 of the TFT 2 is electrically connected to the organic light emitting diode OLED via a portion of a transparent conductive layer 6. In addition, the pixel structure 1 further includes another TFT (not shown), and the gate 3 of the TFT 2 is electrically connected to a drain 7 of another TFT via another portion of the transparent conductive layer 6.

In the pixel structure of the conventional OLED display panel, the gate of a TFT is electrically connected to the drain of another TFT via the transparent conductive layer. Consequently, when the pixel structure is applied to a top-emission type OLED display panel, the OLED and the transparent conductive layer serving as a connection line have to be disposed separately (not overlapping with each other), causing loss of aperture ratio. Furthermore, in the pixel structure of the conventional OLED display panel, polysilicon is used as the material of semiconductor channel of the TFT. Although polysilicon has high carrier mobility, polysilicon has to be formed by high temperature process and suffers from poor uniformity. For the above reasons, the fabrication cost of the conventional OLED display panel is high, and the application is restricted.

### SUMMARY OF THE INVENTION

It is one of the objectives of the present invention to provide a pixel structure of a conventional organic light emitting diode display panel to increase aperture ratio.

According to the present invention, a pixel structure of a conventional organic light emitting diode display panel is provided. The pixel structure of the electroluminescent display panel includes a substrate, a first patterned conductive layer, an insulating layer, a second patterned conductive layer, an active layer, and an electroluminescent device. The first patterned conductive layer is disposed on the substrate, wherein the first patterned conductive layer includes a gate. The insulating layer is disposed on the substrate and the first patterned conductive layer, wherein the insulating layer has at least one first contact hole partially exposing the gate. The second patterned conductive layer is disposed on the insulating layer, wherein the second patterned conductive layer comprises a first source, a first drain and a second drain, and the second drain is electrically connected to the gate exposed by the first contact hole of the insulating layer. The active layer is disposed on the insulating layer, the active layer partially overlapping with the first source and the first drain, respectively. The first passivation layer is disposed on the second patterned conductive layer and the active layer, wherein the first passivation layer has at least one second contact hole partially exposing one of the first source and the first drain. The electroluminescent device is disposed on the first passivation layer, wherein the electroluminescent device is electrically connected to one of the first source and the first drain exposed by the second contact hole of the first passivation layer.

According to the present invention, a method of forming a pixel structure of an electroluminescent display panel is provided. The method includes the following steps. A substrate is provided. A first patterned conductive layer is formed on the substrate, wherein the first patterned conductive layer comprises a gate. An insulating layer is formed on the substrate and the first patterned conductive layer, and at least one first contact hole partially exposing the gate is formed in the insulating layer. A second patterned conductive layer is formed on the insulating layer, wherein the second patterned conductive layer comprises a first source, a first drain and a second drain, and the second drain is electrically connected to the gate exposed by the first contact hole of the insulating layer. An active layer is formed on the insulating layer, wherein the active layer partially overlaps with the first source and the first drain, respectively. A first passivation layer is formed on the second patterned conductive layer and the active layer, and forming at least one second contact hole partially exposing one of the first source and the first drain in the first passivation layer. An electroluminescent device is formed on the first passivation layer, wherein the electroluminescent device is electrically connected to one of the first source and the first drain exposed by the second contact hole of the first passivation layer.

In the pixel structure of the electroluminescent display panel of the present invention, the second drain of the second TFT is electrically connected to the gate of the first TFT directly without requiring a third conductive layer as a connection line, and thus the light emitting area as well as the aperture ratio is significantly improved.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a cross-sectional view illustrating a pixel structure of a conventional organic light emitting diode display panel.

FIG. 2 is a circuit diagram of a pixel structure of an electroluminescent display panel of the present invention.

FIGS. 3-8 are schematic diagrams illustrating a method of forming a pixel structure of an electroluminescent display panel according to a first embodiment of the present invention.

FIGS. 9-10 are schematic diagrams illustrating a method of forming a pixel structure of an electroluminescent display panel according to a second embodiment of the present invention.

FIGS. 11-12 are schematic diagrams illustrating a method of forming a pixel structure of an electroluminescent display panel according to a third embodiment of the present invention.

FIGS. 13-14 are schematic diagrams illustrating a method of forming a pixel structure of an electroluminescent display panel according to a fourth embodiment of the present invention.

FIGS. 15-16 are schematic diagrams illustrating a method of forming a pixel structure of an electroluminescent display panel according to a fifth embodiment of the present invention.

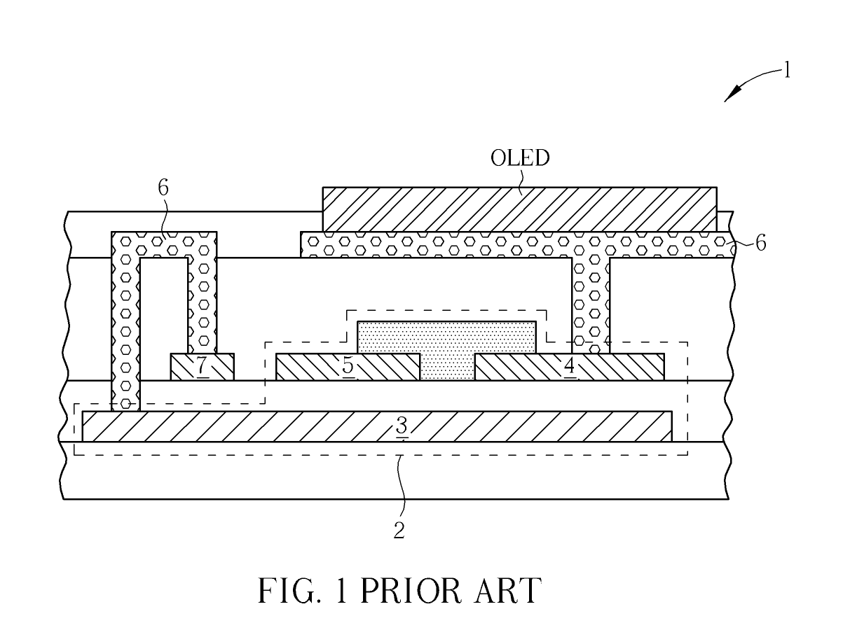

### DETAILED DESCRIPTION

To provide a better understanding of the present invention, preferred embodiments will be made in details. The preferred embodiments of the present invention are illustrated in the accompanying drawings with numbered elements. In addition, the terms such as “first” and “second” described in the present invention are used to distinguish different components or processes, which do not limit the sequence of the components or processes.

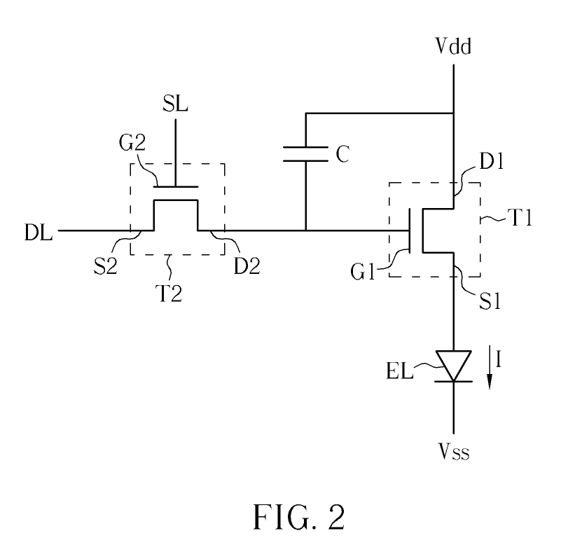

Please refer to FIG. 2. FIG. 2 is a circuit diagram of a pixel structure of an electroluminescent display panel of the present invention. As shown in FIG. 2, the pixel structure of the electroluminescent display panel includes a first switch element, a second switch element, a storage capacitor C and an electroluminescent device EL. In this embodiment, the first switch element and the second switch element are implemented by a first TFT T1 and a second TFT T2 respectively, and the electroluminescent device EL is for instance an OLED, but not limited thereto. The gate G2 of the second TFT T2 is electrically connected to a scan line SL, the second source S2 is electrically connected to a data line DL, and the second drain D2 is electrically to the gate G1 of the first TFT T1 and one electrode of the storage capacitor C. The first drain D1 of the first TFT T1 is electrically connected to a voltage source Vdd and the other electrode of the storage capacitor C. The anode and the cathode of the electroluminescent device EL are electrically connected to the first source S1 of the first TFT T1 and a voltage source Vss, respectively. When emitting light, the scan line SL provides a scanning signal to turn on the gate G2 of the second TFT T2 for a short period of time, and meanwhile the data signal provided by the data line DL will pass the second TFT T2, turning on the gate G1 of the first TFT T1. After the gate G2 of the second TFT T2 turns off, the potential of the data signal is maintained by the storage capacitor C such that the gate G1 of the first TFT T1 can be turned on for a period of time. During the very period of time, the driving current I provided by the voltage source Vdd will continue to pass the electroluminescent device EL to drive the electroluminescent device EL to emit light. In this embodiment, the electroluminescent device EL is disposed between the first source S1 of the first TFT T1 and the voltage source Vss, but not limited thereto. For instance, the electroluminescent device EL may also be disposed between the first drain D1 of the first TFT T1 and the voltage source Vdd.

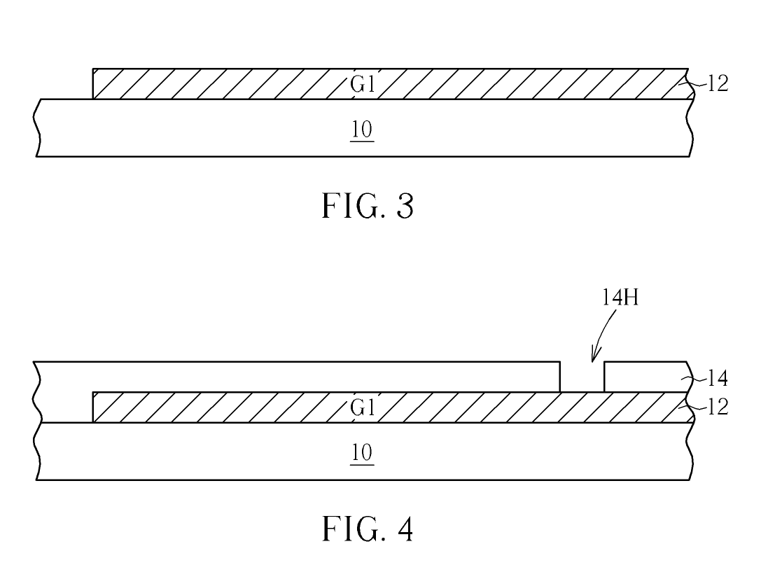

Please refer to FIGS. 3-8, as well as FIG. 2. FIGS. 3-8 are schematic diagrams illustrating a method of forming a pixel structure of an electroluminescent display panel according to a first embodiment of the present invention. As shown in FIG. 3, a substrate 10 is provided. The substrate 10 may be a transparent substrate, but not limited thereto. Then, a first conductive layer, e.g. a metal layer but not limited thereto, is formed on the substrate 10. Subsequently, a first patterning process e.g. a first photolithography-and-etching (PEP) process is performed to pattern the first conductive layer to form a first patterned conductive layer 12. The first patterned conductive layer 12 includes a gate G1 and a gate G2 (shown in FIG. 2). The gate G1 serves as the gate of the first TFT T1, while the gate G2 serves as the gate of the second TFT T2 (shown in FIG. 2).

As shown in FIG. 4, an insulating layer 14 is formed on the substrate 10 and the first patterned conductive layer 12. A second patterning process e.g. a second PEP process is then performed to pattern the insulating layer 14 to form at least one first contact hole 14H in the insulating layer 14, where the first contact hole 14H partially exposes the gate G1. The insulating layer 14 may be made of various insulating material such as silicon oxide, silicon nitride, or silicon oxynitride, but not limited thereto. As shown in FIG. 5, a semiconductor layer is formed on the insulating layer 14, and a third patterning process e.g. a third PEP process is performed to pattern the semiconductor layer to form an active layer 16. The active layer 16 serves as the channel of the first TFT T1. In this embodiment, the material of the active layer 16 may be a metal oxide e.g. indium gallium zinc oxide (IGZO), indium zinc oxide (IZO), zinc oxide (ZnO), or a combination thereof. These materials have advantages such as compatibility to low temperature process, high carrier mobility, high uniformity and high transparency, however, the material of the active layer 16 is not limited to the above materials. For instance, the material of the active layer 16 may also be amorphous crystalline semiconductor material (e.g. amorphous silicon), polycrystalline semiconductor material (e.g. polysilicon), or microcrystalline semiconductor material (e.g. microcrystalline silicon).

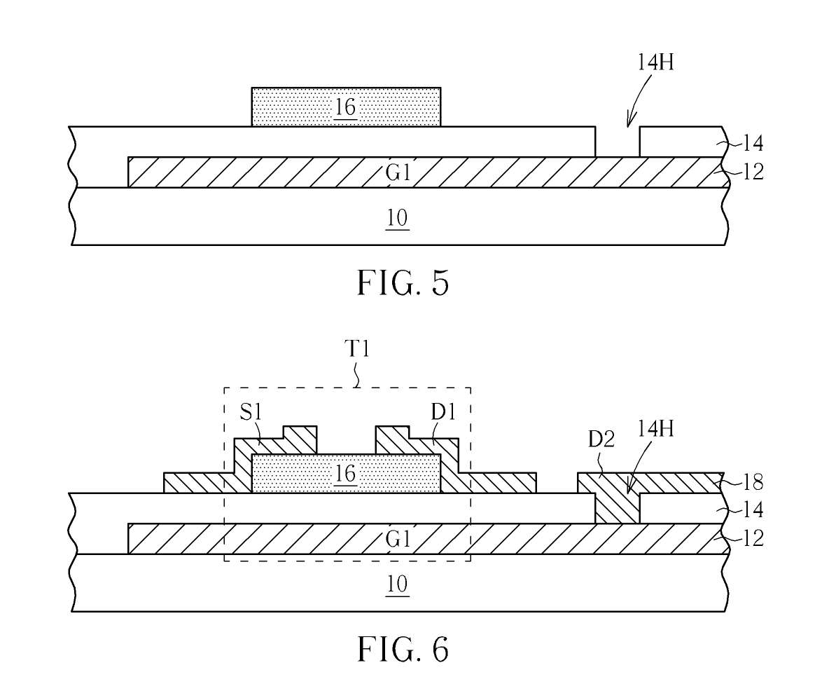

As shown in FIG. 6, a second conductive layer, e.g. a metal layer but not limited thereto, is formed on the insulating layer 14 and the active layer 16. Subsequently, a fourth patterning process e.g. a fourth PEP process is performed to pattern the second conductive layer to form a second patterned conductive layer 18. The second patterned conductive layer 18 includes a first source S1, a second drain D1, a second source S2 (shown in FIG. 2) and a second drain D2. The first source S1 and the first drain D1 serve as the source and the drain of the first TFT T1, respectively. The second source S2 and the second drain D2 serve as the source and the drain of the second TFT T2, respectively. The first source S1 and the first drain D1 covers the top surface of the active layer 16, and partially overlap with the active layer 16, respectively. In this embodiment, the second drain D2 of the second TFT T2 is electrically connected to the exposed gate G1 of the first TFT T1 through the first contact hole 14H of the insulating layer 14. Accordingly, the electrical connection between the first TFT T1 and the second TFT T2 as shown in FIG. 2 is implemented. In this embodiment, the second drain D2 is filled into the first contact hole 14H of the insulating layer 14, and directly electrically connected to the gate G1, but not limited thereto. For example, prior to forming the second drain D2, another conductive layer (not shown) may be filled into the first contact hole 14H of the insulating layer 14 as a contact plug. In this case, the second drain D2 formed successively is electrically connected to the gate G1 via the contact plug.

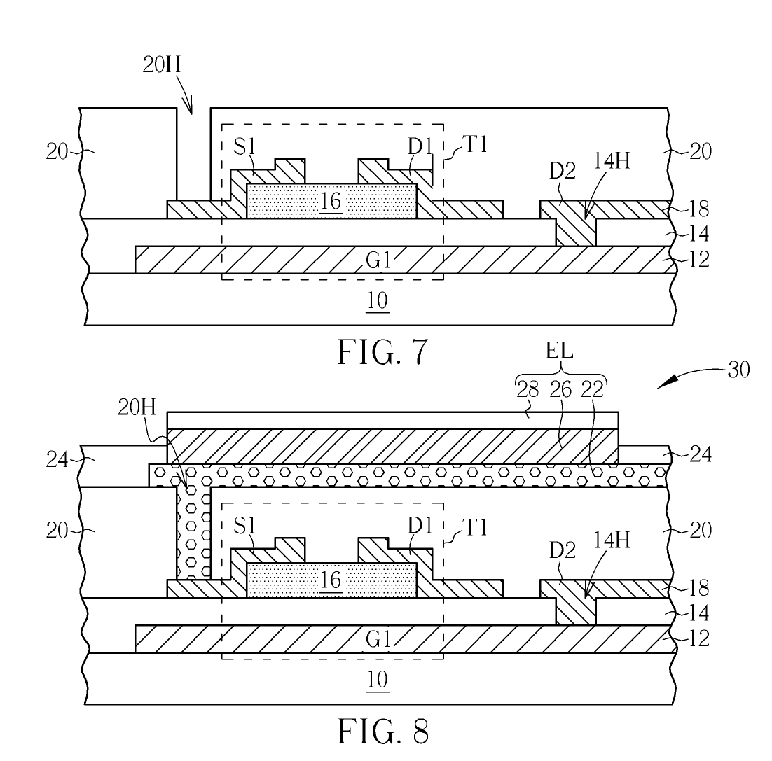

As shown in FIG. 7, a first passivation layer 20 is then formed on the second patterned conductive layer 18 and the active layer 16, and a fifth patterning process e.g. a fifth PEP process is performed to pattern the first passivation layer 20 to form at least one second contact hole 20H in the first passivation layer 20. The second contact hole 20H of the first passivation layer 20 partially exposes one of the first source S1 and the first drain D1. In this embodiment, the second contact hole 20H partially exposes the first source S1, but not limited thereto. For example, if the electroluminescent device EL is disposed between the first drain D1 of the first TFT T1 and the voltage source Vdd, the second contact hole 20H partially exposes the first drain D1. The first passivation layer 20 may be single-layered or composite-layered, and the material of the first passivation layer 20 may be inorganic material, organic material or inorganic/organic composite (hybrid) materials. It is to be noted that if photosensitive organic material is selected as the material of the first passivation layer 20, the fifth patterning process may be implemented by an exposure-and-development process without requiring an etching process.

As shown in FIG. 8, a third conductive layer 22 is formed on the first passivation layer 20, and a sixth patterning process e.g. a sixth PEP process is performed to pattern the third conductive layer 22. The third conductive layer 22 may be made of various transparent conductive materials such as indium tin oxide (ITO), or non-transparent conductive materials such as metal. The third conductive layer 22 is used as the anode of the electroluminescent device EL, and is filled into the second contact hole 20H to electrically connect to one of the first source S1 and the first drain D1 of the first TFT T1. In this embodiment, the third conductive layer 22 is electrically connected to the exposed first source S1 through the second contact hole 20H, but not limited thereto. Subsequently, a second passivation layer 24 is formed on the first passivation layer 20 and the third conductive layer 22, and a seventh patterning process e.g. a seventh PEP process is performed to pattern the second passivation layer 24 to at least partially expose the third conductive layer 22. The second passivation layer 24 may be inorganic material, organic material or inorganic/organic composite (hybrid) materials. It is to be noted that if photosensitive organic material is selected as the material of the second passivation layer 24, the seven patterning process may be implemented by an exposure-and-development process without requiring an etching process. Then, an electroluminescent layer 26 e.g. an organic light emitting layer and a cathode 28 are successively formed on the exposed third conductive layer 22. Since the third conductive layer 22 serves as the anode, the third conductive layer 22, the electroluminescent layer 26 and the cathode 28 therefore form the electroluminescent device EL. In order to improve light emitting efficiency, structural layers such as hole injection layer and hole transporting layer may be formed on the third conductive layer 22 prior to forming the electroluminescent layer 26, and structural layers such as electron transporting layer and electron injection layer may be formed on the electroluminescent layer 26 prior to forming the cathode 28. The pixel structure 30 of the electroluminescent display panel of the present embodiment is accordingly formed as illustrated in FIG. 8.

In this embodiment, the electroluminescent display panel is a top-emission type electroluminescent display panel. Also, the second drain D2 of the second TFT T2 is electrically connected to the exposed gate G1 of the first TFT T1 through the first contact hole 14H of the insulating layer 14, rather than via the third conductive layer 22, thus, the electroluminescent device EL is able to extend to the top of the first TFT T1. In such case, the electroluminescent device EL may at least partially overlap with the first source S1 and the first drain D1, or may entirely overlap with the first source S1 and the first drain D1. The electroluminescent device EL may also at least partially overlap with the first contact hole 14H of the insulating layer 14, or may entirely overlap with the first contact hole 14H of the insulating layer 14. Accordingly, the light emitting area of the pixel structure 30 of the electroluminescent display panel can be significantly improved, thereby increasing aperture ratio.

The pixel structure of the electroluminescent display panel of the present invention is not limited to the aforementioned embodiment. The pixel structure of the electroluminescent display panel and method of making the same of other embodiments will be illustrated in the following passages. In order to compare the differences between different embodiments, same components are denoted by same numerals, and repeated parts are not redundantly described.

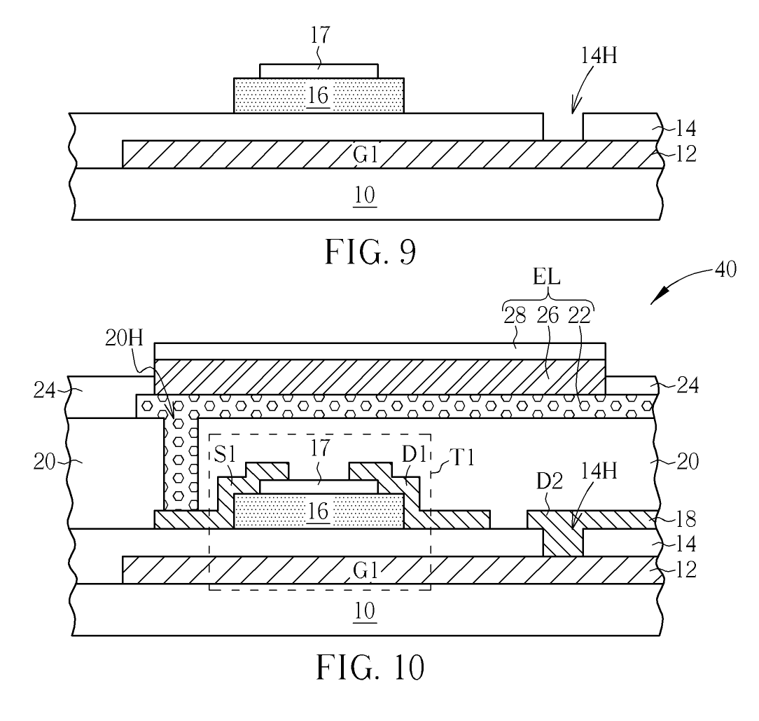

Please refer to FIGS. 9-10, as well as FIGS. 2-5. FIGS. 9-10 are schematic diagrams illustrating a method of forming a pixel structure of an electroluminescent display panel according to a second embodiment of the present invention. FIGS. 9-10 illustrate the steps to be performed subsequent to the steps of FIGS. 3-5. As shown in FIG. 9, after forming the active layer 16 on the insulating layer 14, an etching stop layer 17 is formed on the insulating layer 14 and the active layer 16. Then an eighth patterning process e.g. an eighth PEP process is performed to pattern the etching stop layer 17 to partially remove the etching stop layer 17. Consequently, the etching stop layer 17 only partially covers the top surface of the active layer 16. The material of the etching stop layer 17 may be various dielectric materials such as silicon nitride, but not limited thereto. The formation of the etching stop layer 17 aims at protecting the active layer 16 from being damaged in the subsequent step of patterning the second conductive layer. As shown in FIG. 10, a second patterned conductive layer 18 is formed, and the first source S1 and the first drain D1 of the second patterned conductive layer 18 partially cover the top surface of the etching stop layer 17, respectively. Subsequently, a first passivation layer 20, a third conductive layer 22, a second passivation layer 24 and an electroluminescent device EL are successively formed to accomplish the pixel structure 40 of the electroluminescent display panel of the present embodiment.

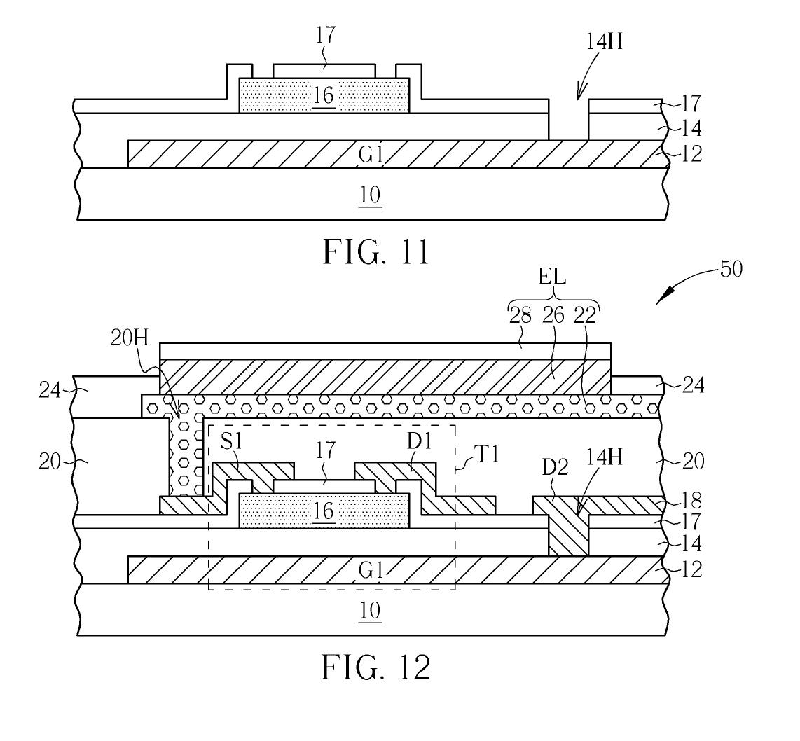

Please refer to FIGS. 11-12, as well as FIGS. 2-5. FIGS. 11-12 are schematic diagrams illustrating a method of forming a pixel structure of an electroluminescent display panel according to a third embodiment of the present invention. FIGS. 11-12 illustrate the steps to be performed subsequent to the steps of FIGS. 3-5. As shown in FIG. 11, different from the second embodiment, the etching stop layer 17 covers a portion of the top surface of the active layer 16, as well as the two side surfaces of the active layer 16 and a portion of the insulating layer 14, but exposes the first contact hole 14H of the insulating layer 14. As shown in FIG. 12, a second patterned conductive layer 18 is formed, and the first source S1 and the first drain D1 of the second patterned conductive layer 18 partially cover the top surface of the etching stop layer 17, respectively. Subsequently, a first passivation layer 20, a third conductive layer 22, a second passivation layer 24 and an electroluminescent device EL are successively formed to accomplish the pixel structure 50 of the electroluminescent display panel of the present embodiment.

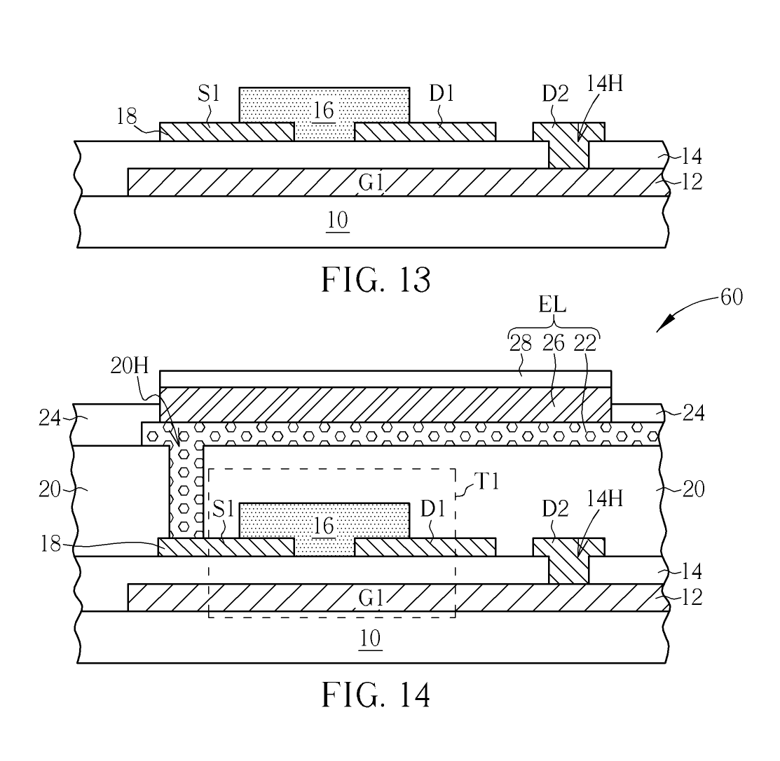

Please refer to FIGS. 13-14, as well as FIGS. 2-4. FIGS. 13-14 are schematic diagrams illustrating a method of forming a pixel structure of an electroluminescent display panel according to a fourth embodiment of the present invention. FIGS. 13-14 illustrate the steps to be performed subsequent to the steps of FIGS. 3-4. As shown in FIG. 13, subsequent to forming the insulating layer 14, a second conductive layer, e.g. a metal layer but not limited thereto, is formed on the insulating layer 14. Then, a third patterning process e.g. a third PEP process is performed to pattern the second conductive layer to form a second patterned conductive layer 18. The second patterned conductive layer 18 includes a first source S1, a second drain D1, a second source S2 (shown in FIG. 2) and a second drain D2. The first source S1 and the first drain D1 serve as the source and the drain of the first TFT T1, respectively. The second source S2 and the second drain D2 serve as the source and the drain of the second TFT T2 (shown in FIG. 2), respectively. In this embodiment, the second drain D2 of the second TFT T2 is electrically connected to the exposed gate G1 of the first TFT T1 through the first contact hole 14H of the insulating layer 14. Accordingly, the electrical connection between the first TFT T1 and the second TFT T2 as shown in FIG. 2 is implemented. Subsequently, a semiconductor layer is formed on the insulating layer 14 and the second patterned conductive layer 18, and a fourth patterning process e.g. a fourth PEP process is performed to pattern the semiconductor layer to form an active layer 16. The active layer 16 at least partially overlaps with the first source S1 and the first drain D1, respectively. As shown in FIG. 14, a first passivation layer 20, a third conductive layer 22, a second passivation layer 24 and an electroluminescent device EL are successively formed on the insulating layer 14, the active layer 16 and the second patterned conductive layer 18 to accomplish the pixel structure 60 of the electroluminescent display panel of the present embodiment.

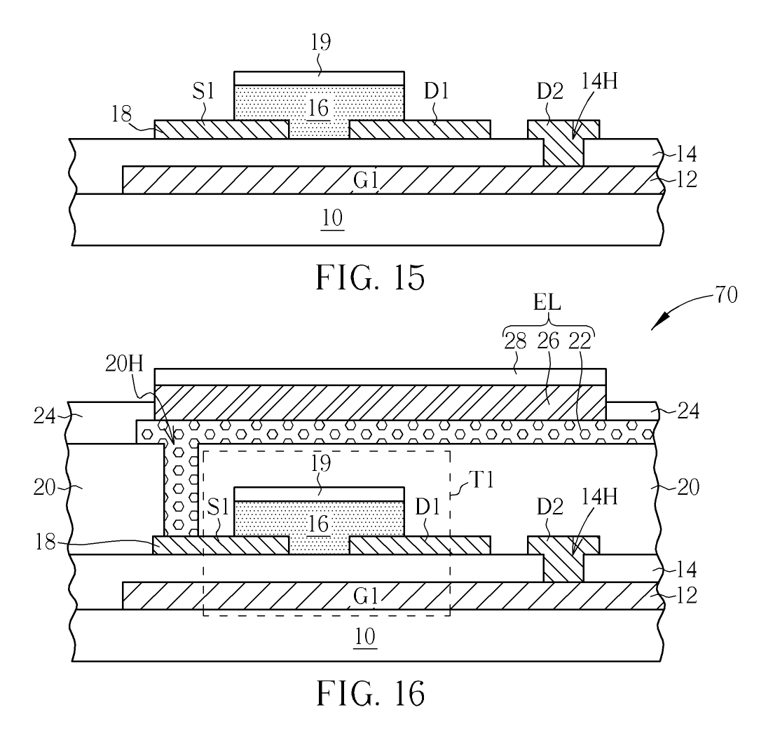

Please refer to FIGS. 15-16, as well as FIGS. 2-4. FIGS. 15-16 are schematic diagrams illustrating a method of forming a pixel structure of an electroluminescent display panel according to a fifth embodiment of the present invention. FIGS. 15-16 illustrate the steps to be performed subsequent to the steps of FIGS. 3-4. As shown in FIG. 15, subsequent to forming the insulating layer 14, a second conductive layer, e.g. a metal layer but not limited thereto, is formed on the insulating layer 14. Then, a third patterning process e.g. a third PEP process is performed to pattern the second conductive layer to form a second patterned conductive layer 18. The second patterned conductive layer 18 includes a first source S1, a second drain D1, a second source S2 (shown in FIG. 2) and a second drain D2. The first source S1 and the first drain D1 serve as the source and the drain of the first TFT T1, respectively. The second source S2 and the second drain D2 serve as the source and the drain of the second TFT T2 (shown in FIG. 2), respectively. In this embodiment, the second drain D2 of the second TFT T2 is electrically connected to the exposed gate G1 of the first TFT T1 through the first contact hole 14H of the insulating layer 14. Accordingly, the electrical connection between the first TFT T1 and the second TFT T2 as shown in FIG. 2 is implemented. Subsequently, a semiconductor layer is formed on the insulating layer 14 and the second patterned conductive layer 18, and a cap layer 19 is formed on the top surface of the semiconductor layer. Then, a fourth patterning process e.g. a fourth PEP process is performed to pattern the semiconductor layer and the cap layer 19 to form an active layer 16 and to make the cap layer 19 correspond to the active layer 16. The active layer 16 at least partially overlaps with the first source S1 and the first drain D1, respectively. The material of the cap layer 19 may be various dielectric materials such as silicon nitride, but not limited thereto. The cap layer 19 is able to isolate the active layer 16 from water vapor and adjust the electrical characteristic of the TFT T1 e.g. current vs. voltage relation. In this embodiment, the cap layer 19 and the active layer 16 are formed by the same patterning process, and thus the cap layer 19 and the active layer 16 have identical pattern. The cap layer 19 and the active layer 16, however, may be formed by different patterning processes, and thus the cap layer 19 and the active layer 16 may have different patterns. For instance, the cap layer 19 may further covers the two side surfaces of the active layer 16. As shown in FIG. 16, a first passivation layer 20, a third conductive layer 22, a second passivation layer 24 and an electroluminescent device EL are successively formed on the insulating layer 14, the cap layer 19 and the second patterned conductive layer 18 to accomplish the pixel structure 70 of the electroluminescent display panel of the present embodiment.

In summary, in the pixel structure of the electroluminescent display panel of the present invention, the second drain of the second TFT is electrically connected to the gate of the first TFT directly without requiring a third conductive layer as a connection line, and thus the light emitting area as well as the aperture ratio is significantly improved. In addition, metal oxide, which possesses the advantages such as compatibility to low temperature process, high carrier mobility, high uniformity and high transparency, may be used as the material of the active layer of the TFT in the pixel structure of the electroluminescent display panel of the present invention.

Those skilled in the art will readily observe that numerous modifications and alterations of the device and method may be made while retaining the teachings of the invention.

What is claimed is:

1. A pixel structure of an electroluminescent display panel, comprising:
a substrate;
a first patterned conductive layer disposed on the substrate, wherein the first patterned conductive layer comprises a gate;
an insulating layer disposed on the substrate and the first patterned conductive layer, wherein the insulating layer has at least one first contact hole partially exposing the gate;
a second patterned conductive layer disposed on the insulating layer, wherein the second patterned conductive layer comprises a first source, a first drain and a second drain, and the second drain is electrically connected to the gate exposed by the first contact hole of the insulating layer;
an active layer disposed on the insulating layer, the active layer partially overlapping with the first source and the first drain, respectively;
a first passivation layer disposed on the second patterned conductive layer and the active layer, wherein the first passivation layer has at least one second contact hole partially exposing one of the first source and the first drain; and
an electroluminescent device disposed on the first passivation layer, wherein the electroluminescent device is electrically connected to one of the first source and the first drain exposed by the second contact hole of the first passivation layer.

2. The pixel structure of the electroluminescent display panel of claim 1, wherein the first source and the first drain partially cover a top surface of the active layer, respectively.

3. The pixel structure of the electroluminescent display panel of claim 2, further comprising an etching stop layer partially covers the top surface of the active layer, and the first source and the first drain partially cover a top surface of the etching stop layer, respectively.

4. The pixel structure of the electroluminescent display panel of claim 3, wherein the etching stop layer further covers two side surfaces of the active layer and a top surface of the insulating layer.

5. The pixel structure of the electroluminescent display panel of claim 1, wherein the active layer partially covers a top surface of the first source and a top surface of the first drain, respectively.

6. The pixel structure of the electroluminescent display panel of claim 5, further comprising a cap layer covering a top surface of the active layer.

7. The pixel structure of the electroluminescent display panel of claim 6, wherein the cap layer further covers two side surfaces of the active layer.

8. The pixel structure of the electroluminescent display panel of claim 6, wherein the cap layer comprises a silicon oxide layer, a silicon nitride layer or a silicon oxynitride layer.

9. The pixel structure of the electroluminescent display panel of claim 1, wherein the active layer comprises a metal oxide.

10. The pixel structure of the electroluminescent display panel of claim 9, wherein the metal oxide comprises indium gallium zinc oxide (IGZO), indium zinc oxide (IZO), zinc oxide (ZnO), or a combination thereof.

11. The pixel structure of the electroluminescent display panel of claim 9, wherein the metal oxide comprises an amorphous metal oxide.

12. The pixel structure of the electroluminescent display panel of claim 1, wherein a portion of the electroluminescent device at least partially overlaps with the first contact hole of the insulating layer.

13. The pixel structure of the electroluminescent display panel of claim 1, wherein a portion of the electroluminescent device at least partially overlaps with the first source and the first drain.

14. A method of forming a pixel structure of an electroluminescent display panel, the method comprising:
providing a substrate;
forming a first patterned conductive layer on the substrate, wherein the first patterned conductive layer comprises a gate;
forming an insulating layer on the substrate and the first patterned conductive layer, and forming at least one first contact hole partially exposing the gate in the insulating layer;
forming a second patterned conductive layer on the insulating layer, wherein the second patterned conductive layer comprises a first source, a first drain and a second drain, and the second drain is electrically connected to the gate exposed by the first contact hole of the insulating layer;
forming an active layer on the insulating layer, wherein the active layer partially overlaps with the first source and the first drain, respectively;
forming a first passivation layer on the second patterned conductive layer and the active layer, and forming at least one second contact hole partially exposing one of the first source and the first drain in the first passivation layer; and
forming an electroluminescent device on the first passivation layer, wherein the electroluminescent device is electrically connected to one of the first source and the first drain exposed by the second contact hole of the first passivation layer.

15. The method of forming the pixel structure of the electroluminescent display panel of claim 14, wherein the step of forming the second patterned conductive layer is performed subsequent to the step of forming the active layer, and the first source and the first drain partially cover a top surface of the active layer, respectively.

16. The method of forming the pixel structure of the electroluminescent display panel of claim 15, further comprising forming an etching stop layer partially covering the top surface of the active layer prior to the step of forming the second patterned conductive layer, wherein the first source and the first drain partially cover a top surface of the etching stop layer, respectively.

17. The method of forming the pixel structure of the electroluminescent display panel of claim 16, wherein the etching stop layer further covers two side surfaces of the active layer and a top surface of the insulating layer.

18. The method of forming the pixel structure of the electroluminescent display panel of claim 14, wherein the step of forming the active layer is performed subsequent to the step of forming the second patterned conductive layer, and the active layer partially covers a top surface of the first source and a top surface of the first drain, respectively.

19. The method of forming the pixel structure of the electroluminescent display panel of claim 18, further comprising forming a cap layer covering a top surface of the active layer prior to the step of forming the first passivation layer.

20. The method of forming the pixel structure of the electroluminescent display panel of claim 19, wherein the cap layer further covers two side surfaces of the active layer.

21. The method of forming the pixel structure of the electroluminescent display panel of claim 14, wherein a portion of the electroluminescent device at least partially overlaps with the first contact hole of the insulating layer.

22. The method of forming the pixel structure of the electroluminescent display panel of claim 14, wherein a portion of the electroluminescent device at least partially overlaps with the first source and the first drain.
